(19) United States
(12) Patent Application Publication
(10) Pub. No.: US 2025/0291447 A1
(43) Pub. Date: Sep. 18, 2025

(54) INPUT SENSING PART AND DISPLAY DEVICE INCLUDING THE SAME

(71) Applicant: Samsung Display Co., Ltd., Yongin-si (KR)

(72) Inventors: WONJUN CHOI, Yongin-si (KR); WONKYU KWAK, Yongin-si (KR); KICHEOL KIM, Yongin-si (KR)

(21) Appl. No.: 19/072,571

(22) Filed: Mar. 6, 2025

(30) Foreign Application Priority Data
Mar. 12, 2024 (KR) 10-2024-0034598

(51) Int. Cl. G06F 3/044; H10K 59/40

(52) U.S. Cl. CPC G06F 3/0446; G06F 3/0443; G06F 3/0448; H10K 59/40

(57) ABSTRACT

An input sensing part includes: a plurality of sensing electrodes in an active area; a plurality of sensing lines connected to the sensing electrodes, respectively; and a plurality of first dummy electrodes in an inactive area around the active area, wherein a hole is defined in the active area, and wherein the sensing electrodes include: a plurality of first sensing electrodes adjacent to the hole, and connected to the first dummy electrodes, respectively; and a plurality of second sensing electrodes spaced apart from the hole further than the first sensing electrodes.

### CROSS-REFERENCE TO RELATED APPLICATION

The present application claims priority to and the benefit of Korean Patent Application No. 10-2024-0034598, filed on Mar. 12, 2024, in the Korean Intellectual Property Office, the entire disclosure of which is incorporated by herein reference.

### BACKGROUND

Aspects of some embodiments of the present disclosure described herein relate to an input sensing part and a display device including the same.

In general, electronic devices, such as smartphones, digital cameras, laptop computers, navigation systems, and smart televisions that provide images to users include a display device for displaying images. The display device generates images, and displays the generated images to the users through a display screen. The display device may include an input device, such as a display panel for generating images and an input sensing part (or input sensor).

The above information disclosed in this Background section is only for enhancement of understanding of the background and therefore the information discussed in this Background section does not necessarily constitute prior art.

### SUMMARY

Aspects of some embodiments of the present disclosure include an input sensing part that may relatively improve a uniformity of capacitances formed by sensing electrodes, and a display device including the same.

In a display device, an input sensing part may be located on the display panel, and may sense a touch by the user as an external input. The input sensing part that is operated in a self-sensing mode may include a plurality of sensing electrodes, and a plurality of sensing lines connected to the sensing electrodes, respectively. The sensing lines may be connected to pads.

As the shapes of display devices may be formed in various ways or shapes, the shapes of the sensing electrodes may also be formed differently from each other. For example, when some of edges of the display device are formed in a curved shape, the edges of the sensing electrodes, which are adjacent to the curved edge, may be formed in a curved shape or pattern, but the sensing electrodes that are spaced apart from the edge of the display device may be formed in a rectangular shape or pattern. When the shapes of the sensing electrodes are different, the capacitances formed by the sensing electrodes may not be uniform.

According to some embodiments of the present disclosure, an input sensing part includes a plurality of sensing electrodes in an active area, a plurality of sensing lines connected to the sensing electrodes, respectively, and a plurality of first dummy electrodes in an inactive area around the active area, a hole is defined in the active area, and the sensing electrodes include a plurality of first sensing electrodes adjacent to the hole, and connected to the first dummy electrodes, respectively, and a plurality of second sensing electrodes spaced apart from the hole further than the first sensing electrodes.

According to some embodiments of the present disclosure, a display device includes a display panel, and an input sensing part on the display panel, the input sensing part includes a plurality of sensing electrodes in an active area, and a plurality of first dummy electrodes in an inactive area around the active area, a hole is defined in the active area, and the sensing electrodes include a plurality of first sensing electrodes adjacent to the hole, and connected to the first dummy electrodes, respectively, and a plurality of second sensing electrodes spaced apart from the hole further than the first sensing electrodes, and a size of the first dummy electrodes is set differently depending on a size of the sensing electrodes.

### BRIEF DESCRIPTION OF THE DRAWINGS

The above and other aspects and characteristics of some embodiments of the present disclosure will become more apparent by describing in more detail aspects of some embodiments thereof with reference to the accompanying drawings.

FIG. 1 is a view illustrating an interior of a vehicle, in which a display device is located, according to some embodiments of the present disclosure.

FIG. 2 is a perspective view of the display device illustrated in FIG. 1.

FIG. 3 is a view illustrating, by way of example, a cross section of the display device illustrated in FIG. 2.

FIG. 4 is a view illustrating, by way of example, a cross section of a display panel illustrated in FIG. 3.

FIG. 5 is a plan view of the display panel illustrated in FIG. 3.

FIG. 6 is a view illustrating, by way of example, a cross section of any one pixel illustrated in FIG. 5.

FIG. 7 is a plan view of an input sensing part illustrated in FIG. 3.

FIG. 8 is an enlarged view illustrating sensing electrodes that are in a first area A1 illustrated in FIG. 7 and pads that are connected to the sensing electrodes located in the first area A1.

FIG. 9 is an enlarged view of a sensing electrode, for illustrating a detailed configuration of any one sensing electrode illustrated in FIG. 8.

FIG. 10 is a cross-sectional view taken along the line I-I′ illustrated in FIG. 9.

FIG. 11 is an enlarged view illustrating a portion of an input sensing part that is adjacent to a hole illustrated in FIG. 7.

FIG. 12 is a cross-sectional view taken along the lines II-II′ and III-III′ illustrated in FIG. 11.

FIG. 13 is an enlarged view of a portion of an input sensing part that is adjacent to a corner part located at a left upper end of an active area illustrated in FIG. 7.

FIG. 14 is an enlarged view of a portion of an input sensing part (or input sensor or input sensing component) that is adjacent to a corner part at a left lower end of an active area illustrated in FIG. 7.

FIGS. 15 and 16 are views illustrating a connection configuration of third sensing electrodes that are adjacent to corner parts, and second dummy electrodes according to some embodiments of the present disclosure.

FIG. 17 is a more planar view illustrating sensing electrodes and sensing lines illustrated in FIG. 7.

FIG. 18 is a cross-sectional view taken along the line IV-IV′ illustrated in FIG. 17.

FIG. 19 is a cross-sectional view taken along the line V-V′ illustrated in FIG. 17.

FIG. 20 is a cross-sectional view taken along the line VI and VI′ illustrated in FIG. 17.

FIG. 21 is a plan view of an input sensing part according to some embodiments of the present disclosure.

FIG. 22 is an enlarged view of sensing electrodes that are in a second area A2 illustrated in FIG. 21.

FIG. 23 is an enlarged view illustrating sensing electrodes in a state, in which dummy electrodes are removed from a third area A3 illustrated in FIG. 21.

FIG. 24 is an enlarged view of sensing electrodes a dummy electrode that are in a third area A3 illustrated in FIG. 21.

### DETAILED DESCRIPTION

In the specification, when it is mentioned that a component (or an area, a layer, a part, or the like) is “located on”, “connected to”, or “coupled to” another component, it means that the former component may be directly located on, connected to, or coupled to the latter component or a third component may be located between the components.

The same reference numerals denote the same components. Furthermore, in the drawings, thicknesses, ratios, dimensions of the components are exaggerated for an effective description of the technical contents.

The term “and/or” includes one or more combinations that may be defined by the associated components.

Furthermore, in describing the various components, the terms, such as first and second may be used, but the present disclosure is not limited by the terms. The terms are simply for distinguishing the components. For example, a first component may be named a second component, and similarly the second component also may be named the first component while not departing from the scope of the present disclosure. A singular expression includes a plural expression unless an exemption is explicitly described in the context.

Furthermore, the terms, such as “under”, “below”, “on”, and “above”, are used to describe an associative relationship between the components illustrated in the drawings. The terms are relative concepts, and are described with respect to directions indicated in the drawings.

Unless otherwise defined, all terms, including technical and scientific terms, used herein have the same meaning as commonly understood by those skilled in the art to which the present disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

When the terms, such as “comprise” and/or “comprising”, is used in the specification, it should be understood that they specify presence of the above-mentioned features, numbers, steps, operations, components, parts, and/or combinations thereof, and do not exclude presence or addition of one or more other numbers, steps, operations, components, parts, and/or combinations thereof.

Hereinafter, aspects of some embodiments of the present disclosure will be described in more detail with reference to the drawings.

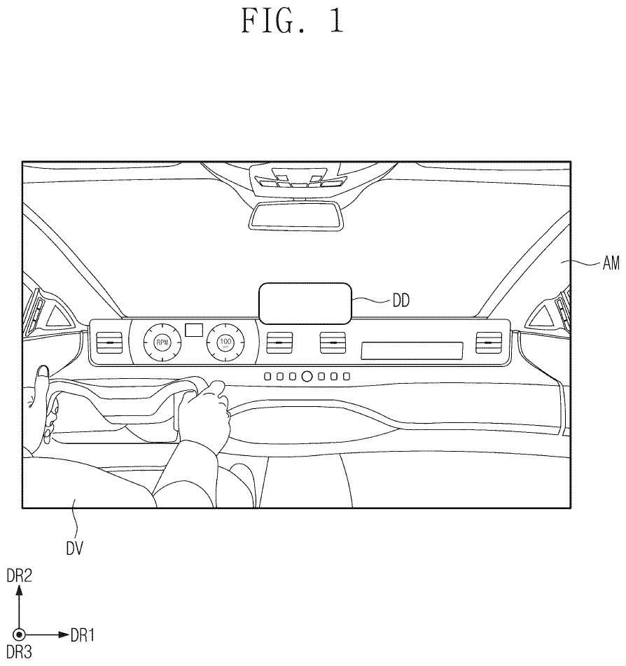

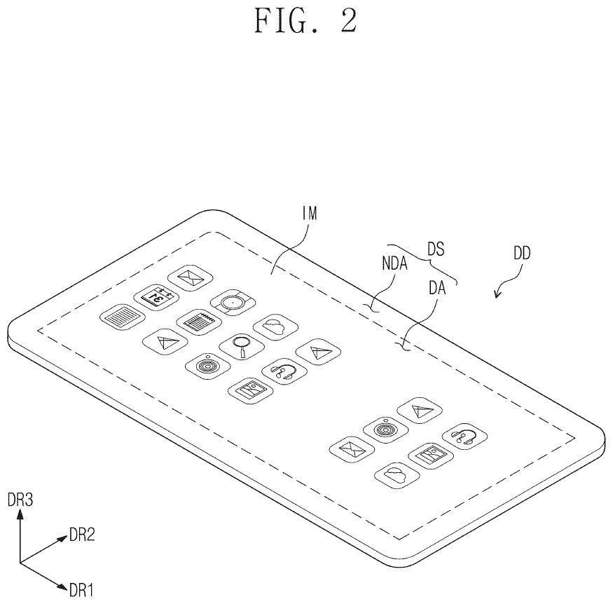

FIG. 1 is a view illustrating an interior of a vehicle, in which a display device is arranged, according to some embodiments of the present disclosure. FIG. 2 is a perspective view of the display device illustrated in FIG. 1.

Referring to FIG. 1, a display device DD may be located in an interior of a vehicle AM. The display device DD may be located in the interior of the vehicle AM to provide various information to the driver DV (or the user). The display device DD may display images regarding, for example, weather, speed, a map, or a movie, to the driver DV. The display device DD may be a touch display that is operated in response to a touch input by the driver DV.

Referring to FIGS. 1 and 2, the display device DD may have a plane that is defined by a first direction DR1 and a second direction DR2 that cross each other. The display device DD may have long sides that extend in the first direction DR1 and short sides that extend in the second direction DR2. Corner parts of the display device DD, which connect the long sides and the short sides, may have a curved shape.

Hereinafter, a direction that is perpendicular (or substantially perpendicular) to the plane defined by the first direction DR1 and the second direction DR2 is defined as a third direction DR3. Furthermore, in the specification, the meaning of “when viewed on a plane” or “in a plan view” is defined as a state, in which it is viewed from the third direction DR3.

A front surface of the display device DD may be defined as a display surface DS, and may have a plane that is defined by the first direction DR1 and the second direction DR2. Images IM that are produced by the display device DD may be provided to the user through the display surface DS.

The display surface DS may include a display area DA, and a non-display area NDA around (e.g., in a periphery or outside a footprint of) the display area DA. The display area DA may display images, and the non-display area NDA may not display an image. The non-display area NDA may surround (e.g., in a periphery or outside a footprint of) the display area DA, and may define a edge of the display device DD printed in a specific color.

Although a display device DD for a vehicle is illustrated by way of example, embodiments according to the present disclosure are not limited thereto. For example, the display device DD according to some embodiments of the present disclosure may be used in an electronic device, such as a smartphone, a digital camera, a laptop computer, a monitor, and a smart television, which provides an image to the user.

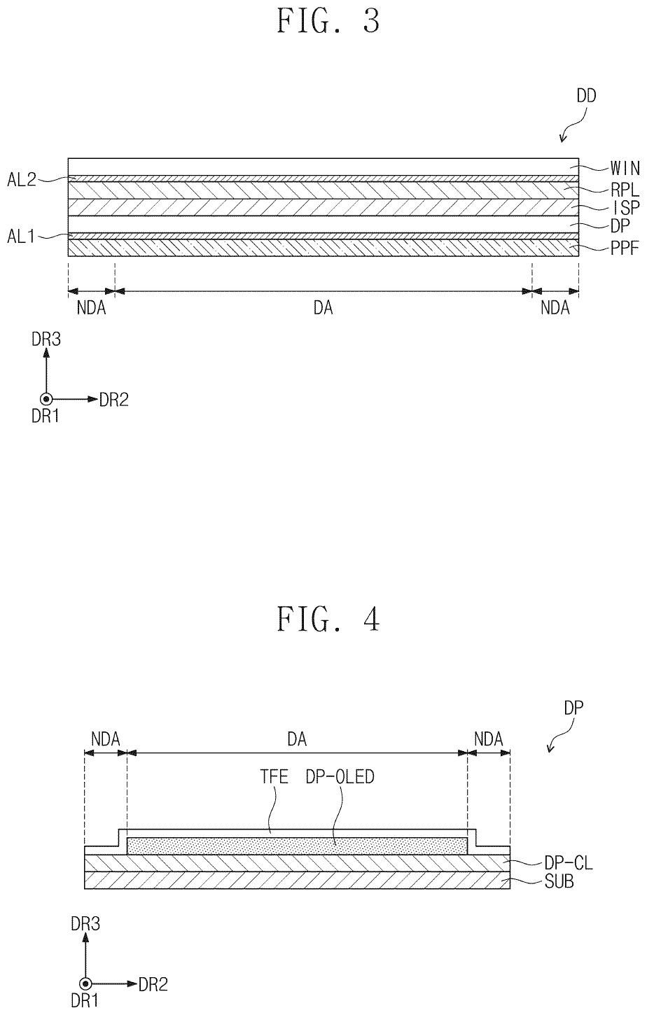

FIG. 3 is a view illustrating, by way of example, a cross section of the display device illustrated in FIG. 2.

By way of example, a cross section of the display device DD, which is viewed from the first direction DR1, is illustrated in FIG. 3.

Referring to FIG. 3, the display device DD may include a display panel DP, an input sensing part ISP, a reflection preventing layer RPL, a window WIN, a panel protection film PPF, and first and second adhesive layers AL1 and AL2.

The display panel DP according to some embodiments of the present disclosure may be a light emitting display panel. For example, the display panel DP may be an organic light emitting display panel or an inorganic light emitting display panel. A light emission layer of the organic light emitting display panel may include an organic light emitting material. The light emission layer of the inorganic light emitting display panel may include a quantum dot, a quantum rod, and the like. Hereinafter, the display panel DP is described as an organic light emitting display panel.

The input sensing part ISP may be located on the display panel DP. The input sensing part ISP may include a plurality of sensing parts for sensing an external input in a capacitive manner. When the display device DD is manufactured, the input sensing part ISP may be manufactured directly on the display panel DP. However, embodiments according to the present disclosure are not limited thereto, and the input sensing part ISP may be manufactured as a separate panel from the display panel DP, and may be attached to the display panel DP by an adhesive layer.

The reflection preventing layer RPL may be located on the input sensing part ISP. When the display device DD is manufactured, the reflection preventing layer RPL may be manufactured directly on the input sensing part ISP. However, embodiments according to the present disclosure are not limited thereto, and the reflection preventing layer RPL is manufactured as a separate panel, and may be attached to the input sensing part ISP by an adhesive layer.

The reflection preventing layer RPL may be defined as an external light reflection preventing film. The reflection preventing layer RPL may reduce a reflectance of the external light that is input from the display device DD toward the display panel DP. The external light may not be visually recognized by the user due to the reflection preventing layer RPL.

When the external light that travels toward the display panel DP is reflected from the display panel DP and is provided again to an external user, the user may visually recognize the external light like a mirror. To prevent or reduce this phenomenon, by way of example, the reflection preventing layer RPL may include a plurality of color filters that display the same colors as those (e.g., corresponding ones) of the pixels of the display panel DP.

The color filters may filter external light with the same colors as those of the pixels. In this case, the external light may not be visually recognized or perceived by the user. However, embodiments according to the present disclosure are not limited thereto, and the reflection preventing layer RPL may include a retarder and/or a polarizer to reduce the reflectance of the external light.

The window WIN may be located on the reflection preventing layer RPL. The window WIN may protect the display panel DP, the input sensing part ISP, and the reflection preventing layer RPL from external scratches and impacts.

The panel protection film PPF may be located under the display panel DP. The panel protection film PPF may protect a lower portion of the display panel DP. The panel protection film PPF may include a flexible plastic material, such as polyethylene terephthalate (PET).

A first adhesive layer AL1 may be located between the display panel DP and the panel protection film PPF, and the display panel DP and the panel protection film PPF may be combined with each other by the first adhesive layer AL1. A second adhesive layer AL2 may be located between the window WIN and the reflection preventing layer RPL, and the window WIN and the reflection preventing layer RPL may be combined with each other by the second adhesive layer AL2.

FIG. 4 is a view illustrating, by way of example, a cross section of a display panel illustrated in FIG. 3.

By way of example, a cross section of the display panel DP, which is viewed from the first direction DR1, is illustrated in FIG. 4.

Referring to FIG. 4, the display panel DP may include a substrate SUB, a circuit element layer DP-CL that is located on the substrate SUB, a display element layer DP-OLED that is located on the circuit element layer DP-CL, and a thin film encapsulation layer TFE that is located on the display element layer DP-OLED.

The substrate SUB may include a display area DA, and a non-display area NDA around the display area DA. The substrate SUB may include glass, or may include a flexible plastic material, such as polyimide (PI). The display element layer DP-OLED may be located on the display area DA.

A plurality of pixels may be located on the circuit element layer DP-CL and the display element layer DP-OLED. Each of the pixels may include a transistor that is located in the circuit element layer DP-CL, and a light emission element that is located in the display element layer DP-OLED and is connected to the transistor.

A thin film encapsulation layer TFE may be located on the circuit element layer DP-CL to cover the display element layer DP-OLED. The thin film encapsulation layer TFE may protect the pixels from moisture, oxygen, and external foreign substances.

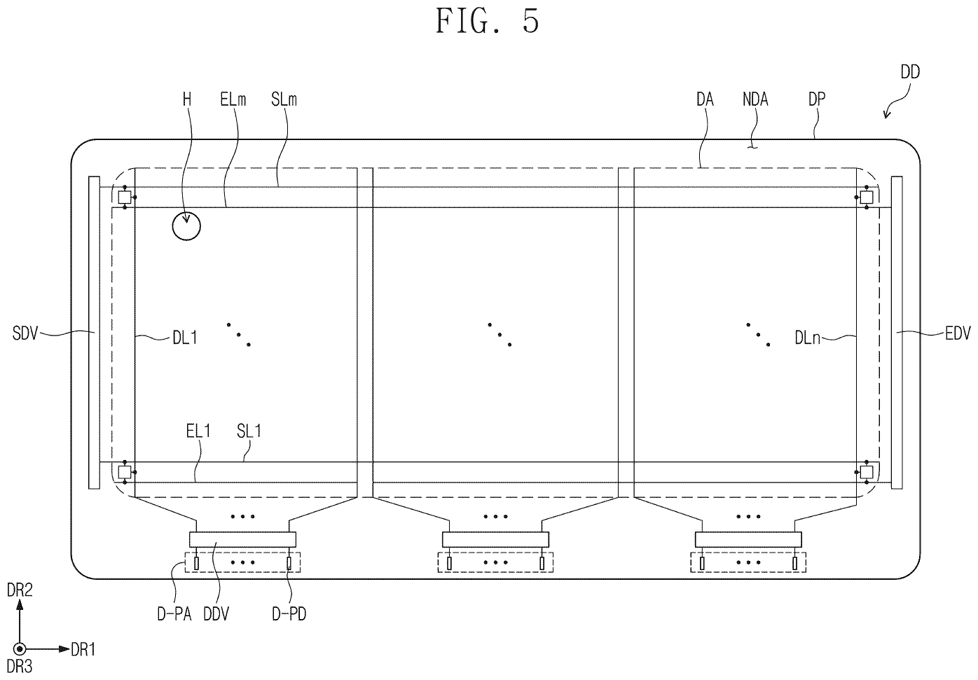

FIG. 5 is a plan view of the display panel illustrated in FIG. 3.

Referring to FIG. 5, the display device DD may include a display panel DP, a scan driver SDV, a plurality of data drivers DDV (data drivers), a light emission driver EDV, and a plurality of pads D-PD.

The display panel DP may have long sides that extend in the first direction DR1 and short sides that extend in the second direction DR2. Corner parts of the display panel DP, which connect the long sides and the short sides, may have a curved shape that is convex outward.

The display panel DP may include a display area DA, and a non-display area NDA that surrounds the display area DA. The display area DA may have a shape corresponding to a edge of the display panel DP. Accordingly, the display area DA may have long sides that extend in the first direction DR1 and short sides that extend in the second direction DR2, and the corner parts of the display area DA, which connecting the long sides and the short sides, may have a curved shape that is convex outward.

The display panel DP may include a plurality of pixels PX, a plurality of scan lines SL1 to SLm, a plurality of data lines DL1 to DLn, and a plurality of light emission lines EL1 to ELm. “M” and “n” are natural numbers.

The pixels PX may be located in the display area DA. The scan driver SDV and the light emission driver EDV may be located in a non-display area NDA that are adjacent to opposite sides of the display panel DP, which are opposite to each other in the first direction DR1. The data drivers DDV may be located in non-display area NDAs that are adjacent to one of opposite sides of the display panel DP, which are opposite to each other in the second direction DR2. When viewed on a plane (or in a plan view), the data drivers DDV may be adjacent to a lower end of the display panel DP.

The scan lines SL1 to SLm may extend in the first direction DR1 and, may be connected to the pixels PX and the scan driver SDV. The data lines DL1 to DLn may extend in the second direction DR2, and may be connected to the pixels PX and the data drivers DDV. The light emission lines EL1 to ELm may extend in the first direction DR1, and may be connected to the pixels PX and the light emission driver EDV.

The data drivers DDV may be arranged in the first direction DR1. A specific number of data lines may be connected to each of the data drivers DDV. For example, three data drivers DDV are illustrated, but the number of data drivers DDV is not limited thereto. For example, as the left and right extents of the display panel DP increase, the number of data drivers DDV may also increase.

The pads D-PD may be located on the non-display area NDA that is adjacent to a lower end of the display panel DP, and may be closer to a lower end of the display panel DP than the data drivers DDV. The data drivers DDV may be connected to the pads D-PD. The data lines DL1 to DLn may be connected to the data drivers DDV, and the data drivers DDV may be connected to the pads D-PD corresponding to the data lines DL1 to DLn.

A plurality of pad areas D-PA corresponding to the data drivers DDV, respectively, may be defined on the display panel DP. The pad areas D-PA may be closer to a lower end of the display panel DP than the data drivers DDV. The pad areas D-PA may be arranged in the first direction DR1, and may be adjacent to the data drivers DDV in the second direction DR2, respectively. A specific number of pads D-PD may be located in each of the pad areas D-PA.

According to some embodiments, the display device DD may further include a timing controller for controlling operations of the scan driver SDV, the data driver DDV, and the light emission driver EDV. The timing controller may be connected to the pads D-PD through a printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The light emission driver EDV generates a plurality of light emitting signals, and the light emitting signals may be applied to the pixels PX through the light emission lines EL1 to ELm.

The pixels PX may receive data voltages in response to scan signals. The pixels PX may display an image by emitting light having a luminance corresponding to data voltages in response to light emission signals.

A hole “H” may be defined in the display panel DP. The hole “H” may be defined in the display area DA. The hole “H” may be adjacent to an upper side and a left side of the display area DA, but a position of the hole “H” is not limited thereto. The hole “H” may be defined while passing through a portion of the display panel DP in the third direction DR3.

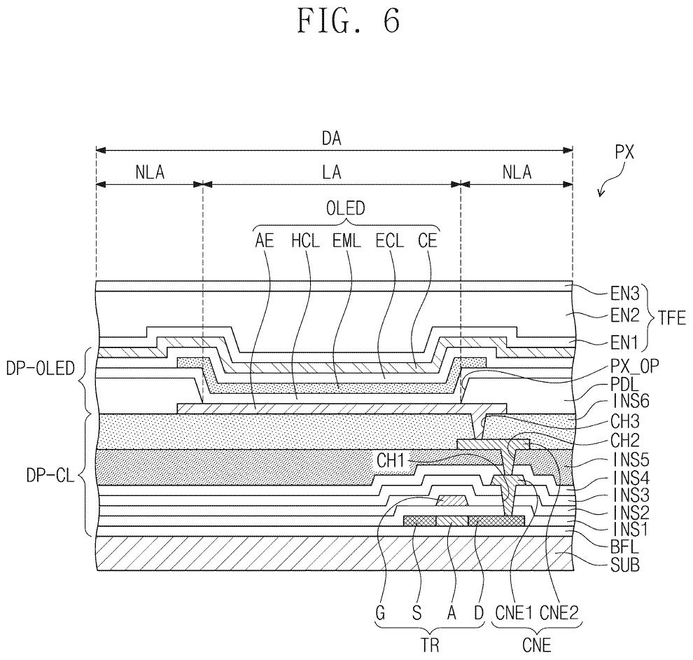

FIG. 6 is a view illustrating, by way of example, a cross section of any one pixel illustrated in FIG. 5.

Referring to FIG. 6, the pixel PX may include a transistor TR and a light emission element OLED. The light emission element OLED may include a first electrode AE (or an anode), a second electrode CE (or a cathode), a hole control layer HCL, an electron control layer ECL, and a light emission layer EML.

The transistor TR and the light emission element OLED may be located on the substrate SUB. Although one transistor TR is illustrated by way of example, embodiments are not limited thereto, and the pixel PX may include a plurality of transistors and at least one capacitor for driving the light emission element OLED.

The display area DA may include a light emission area LA corresponding to each of the pixels PX and a non-light emission area NLA around the light emission area LA. The light emission element OLED may be located in the light emission area LA.

A buffer layer BFL may be located on the substrate SUB, and the buffer layer BFL may be an inorganic layer. A semiconductor pattern may be located on the buffer layer BFL. The semiconductor pattern may include polysilicon, amorphous silicon, or metal oxide.

The semiconductor pattern may be doped with an N-type dopant or a P-type dopant. The semiconductor pattern may include a high doping area and a low doping area. A conductivity of the high doping area may be greater than that of the low doping area, and may serve (or substantially serve) as a source electrode and a drain electrode of the transistor TR. The low doping area may correspond (or substantially correspond) to an active (or a channel) of the transistor.

A source “S”, an active “A”, and a drain “D” of the transistor TR may be formed from a semiconductor pattern. A first insulation layer INS1 may be located on the semiconductor pattern. A gate “G” of the transistor TR may be located on a first insulation layer INS1. A second insulation layer INS2 may be located on the gate “G”. A third insulation layer INS3 may be located on the second insulation layer INS2.

The connection electrode CNE may include a first connection electrode CNE1 and a second connection electrode CNE2 to connect the transistor TR to the light emission element OLED. The first connection electrode CNE1 may be located on the third insulation layer INS3, and may be connected to the drain “D” through first contact holes CH1 that are defined in the first to third insulation layers INS1 to INS3.

A fourth insulation layer INS4 may be located on the first connection electrode CNE1. A fifth insulation layer INS5 may be located on the fourth insulation layer INS4. The second connection electrode CNE2 may be located on the fifth insulation layer INS5. The second connection electrode CNE2 may be connected to the first connection electrode CNE1 through second contact holes CH2 that are defined in the fourth and fifth insulation layers INS4 and INS5.

A sixth insulation layer INS6 may be located on the second connection electrode CNE2. A layer from the buffer layer BFL to the sixth insulation layer INS6 may be defined as a circuit element layer DP-CL. The first to six insulation layers INS1 to INS6 may be an inorganic layer or an organic layer.

A first electrode AE may be located on the sixth insulation layer INS6. The first electrode AE may be connected to the second connection electrode CNE2 through a third contact hole CH3 defined in the sixth insulation layer INS6. A pixel definition film PDL, in which an opening PX_OP for exposing a specific portion of the first electrode AE is defined, may be located on the first electrode AE and the sixth insulation layer INS6.

A hole control layer HCL may be located on the first electrode AE and the pixel definition film PDL. The hole control layer HCL may include a hole transport layer and a hole injection layer.

The light emission layer EML may be located on the hole control layer HCL. The light emission layer EML may be located in an area corresponding to the opening PX_OP. The light emission layer EML may include an organic material and/or an inorganic material. The light emission layer EML may generate any one of red, green, and blue light.

The electron control layer ECL may be located on the light emission layer EML and the hole control layer HCL. The electron control layer ECL may include an electron transport layer and an electron injection layer. The hole control layer HCL and the electron control layer ECL may be arranged in common in the light emission area LA and the non-light emission area NLA.

The second electrode CE may be located on the electronic control layer ECL. The second electrode CE may be arranged in common on the pixels PX. The layer, on which the light emission element OLED is located, may be defined as a display element layer DP-OLED.

The thin film encapsulation layer TFE may be located on the second electrode CE to cover the pixel PX. The thin film encapsulation layer TFE may include a first encapsulation layer EN1 that is located on the second electrode CE, a second encapsulation layer EN2 that is located on the first encapsulation layer EN1, and a third encapsulation layer EN3 that is located on the second encapsulation layer EN2.

The first and third encapsulation layers EN1 and EN3 may include an inorganic encapsulation layer, and may protect the pixel PX from moisture/oxygen. The second encapsulation layer EN2 may include an organic encapsulation layer, and may protect the pixels PX from foreign substances, such as dust particles.

A first voltage may be applied to the first electrode AE through the transistor TR, and a second voltage having a level lower than the first voltage may be applied to the second electrode CE. Holes and electrons that are injected into the light emission layer EML are combined to form excitons, and while the excitons transition to a ground state, the light emission element OLED may emit light.

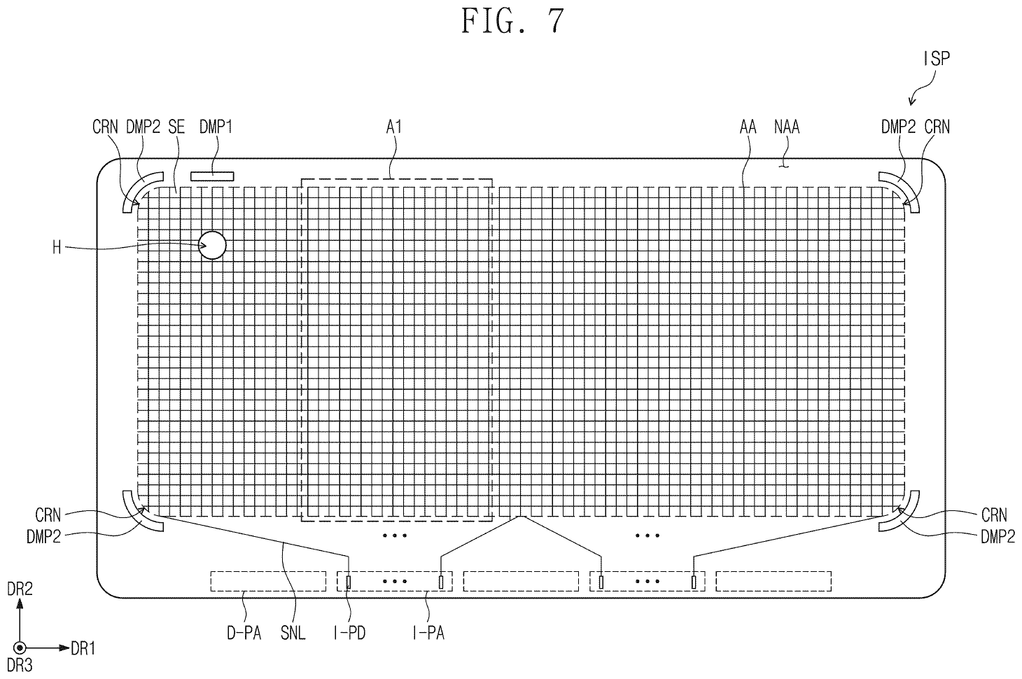

FIG. 7 is a plan view of an input sensing part illustrated in FIG. 3.

By way of example, in FIG. 7, the pad areas D-PA described above are illustrated together with the input sensing part ISP. In FIG. 7, the pad areas D-PA are illustrated by dotted lines.

Referring to FIG. 7, the input sensing part ISP may include a plurality of sensing electrodes SE, a plurality of sensing lines SNL, a plurality of pads I-PD, and a plurality of dummy parts DMP1 and DMP2. The sensing electrodes SE, the sensing lines SNL, and the dummy parts DMP1 and DMP2 may be located on the thin film encapsulation layer TFE.

The input sensing part ISP may have long sides that extend in the first direction DR1 and short sides that extend in the second direction DR2. The corner parts of the input sensing part ISP, which connect the long sides and the short sides of the input sensing part ISP may have an externally convex curved shape.

The input sensing part ISP may include an active area AA and an inactive area NAA around the active area AA. The inactive area NAA may surround the active area AA. The active area AA may overlap the display area DA, and the inactive area NAA may overlap the non-display area NDA.

The active area AA may have a shape corresponding to a edge of the input sensing part ISP. The active area AA may have long sides that extend in the first direction DR1 and short sides that extend in the second direction DR2. The active area AA may have at least one corner part CRN having a curved shape. For example, the corner parts CRN of the active area AA, which connect the long sides and short sides of the active area AA, may have a curved shape that is convex outward.

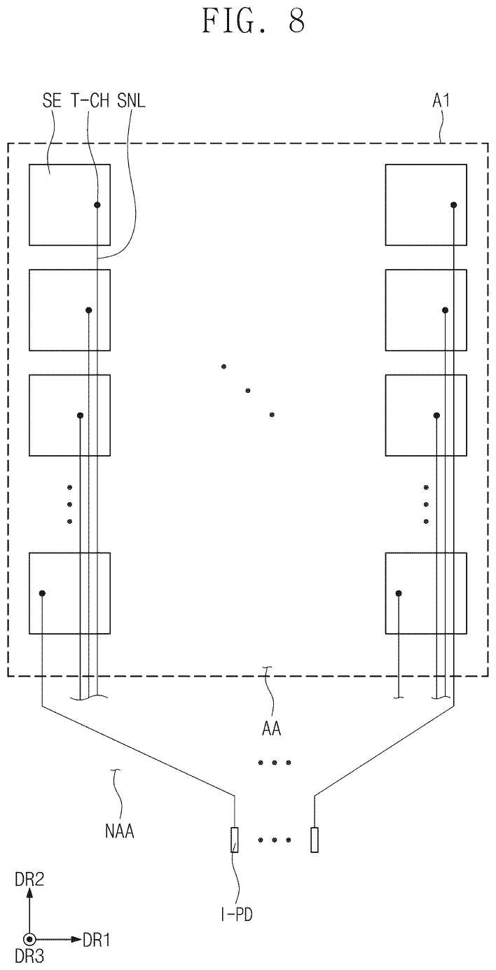

The sensing electrodes SE may be located in the active area AA. The sensing electrodes SE may be arranged in the first direction DR1 and the second direction DR2. For example, a boundary between the sensing electrodes SE is illustrated by a line, and according to some embodiments, the sensing electrodes SE may be arranged to be spaced apart from each other without contacting each other. An arrangement configuration of the sensing electrodes SE will be illustrated and described in more detail with respect to FIGS. 8, 11, 13, and 14.

A hole “H” may be defined in the input sensing part ISP. The hole “H” may be defined in the active area AA. The hole “H” may be defined by passing through a portion of the input sensing part ISP in the third direction DR3. The hole “H” may be defined in the display panel DP and the input sensing part ISP together.

The sensing electrodes SE other than the sensing electrodes SE that is adjacent to the hole “H” and the sensing electrodes SE that is adjacent to the corner parts CRN may have a rectangular shape (or a regular shape) having sides that extending in the first direction DR1 and the second direction DR2. The sensing electrodes SE other than the sensing electrodes SE that is adjacent to the hole “H” and the sensing electrodes SE that is adjacent to the corner parts CRN may be defined as regular sensing electrodes.

The sensing electrodes SE that is adjacent to the hole “H” and the sensing electrodes SE that is adjacent to the corner parts CRN may have an irregular shape that is obtained by deforming a rectangular shape. The sensing electrodes SE that is adjacent to the hole “H” and the sensing electrodes SE that is adjacent to the corner parts CRN may be defined as irregular sensing electrodes.

Edges of the sensing electrodes SE, which face the hole “H”, among the sensing electrodes SE that are adjacent to the hole “H”, may have a curved shape, and edges of the sensing electrodes SE, which do not face the hole “H”, may have sides corresponding to a rectangular shape. The edges of the sensing electrodes SE, which face the hole “H”, may have a curved shape corresponding to a boundary (or the edge of the hole “H”) of the hole “H”.

Edges of the sensing electrodes SE, which face the corner parts CRN, among the sensing electrodes SE that are adjacent to the corner parts CRN, may have a curved shape, and edges of the sensing electrodes SE, which do not face the corner parts CRN, may have sides corresponding to a rectangular shape. Edges of the sensing electrodes SE, which face the corner parts CRN, may have a curved shape corresponding to the corner parts CRN.

The sensing electrodes SE may be arranged in a matrix form to have unique coordinate information. The sensing electrodes SE may be connected to the sensing lines SNL.

Although the sensing lines SNL are illustrated in an inactive area NAA that is adjacent to a lower end of the input sensing part ISP by way of example, according to some embodiments, the sensing lines SNL may be connected to the sensing electrodes SE in the active area AA, and may extend to the inactive area NAA. This configuration will be described in more detail with respect to FIGS. 8, 11, 13, and 14.

The pads I-PD may be located in an inactive area NAA that is adjacent to a lower end of the input sensing part ISP. The sensing lines SNL may be connected to the pads I-PD.

A plurality of pad areas I-PA may be defined in the input sensing part ISP. The pad areas I-PA may be spaced apart from each other in the first direction DR1. A specific number of pads I-PD may be located in each of the pad areas I-PA.

The pad areas I-PA may be located between the pad areas D-PA of the display panel DP. Thus, when viewed on a plane (or in a plan view), the pad areas I-PA may not overlap the pad areas D-PA.

According to some embodiments, an input sensing control unit for controlling an operation of the input sensing part ISP may be connected to the pads I-PD through a printed circuit board.

The dummy parts DMP1 and DMP2 may be located in the inactive area NAA. The dummy parts DMP1 and DMP2 may be adjacent to a edge of the active area AA. The dummy parts DMP1 and DMP2 may include a first dummy part DMP1 and a plurality of second dummy parts DMP2. The first dummy part DMP1 may be adjacent to a portion of a long side of the active area AA, which is adjacent to the hole “H”. The second dummy parts DMP2 may be adjacent to the corner parts CRN, respectively.

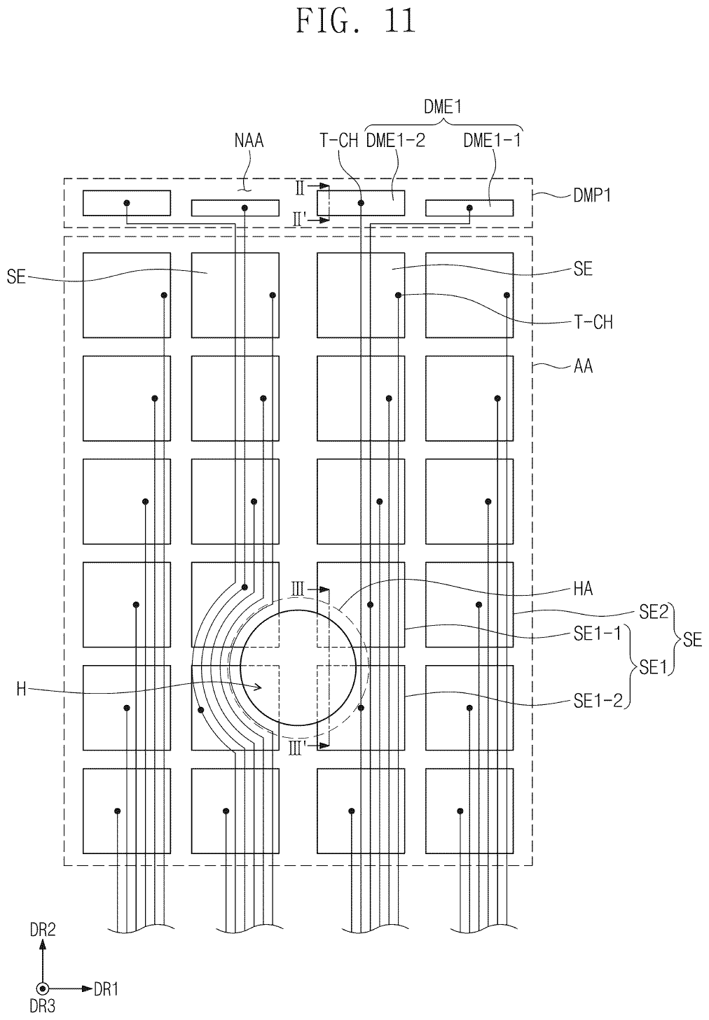

The first dummy part DMP1 may be connected to the sensing electrodes SE that are adjacent to the hole “H”, and the second dummy parts DMP2 may be connected to the sensing electrodes SE that are adjacent to the corner parts CRN. The first and second dummy parts DMP1 and DMP2 may include a hole “H” and a plurality of dummy electrodes that are to be connected to the sensing electrodes SE that are adjacent to the corner parts CRN. This configuration will be described in more detail below with reference to FIGS. 11, 13, and 14.

The input sensing part ISP according to some embodiments of the present disclosure may be driven in a self-sensing mode to acquire coordinate information in a self-cap method. For example, the input sensing controller may apply a driving signal to the sensing electrodes SE through the pads I-PD and the sensing lines SNL, and may receive a sensing signal from the sensing electrodes SE.

FIG. 8 is an enlarged view illustrating sensing electrodes that are located in a first area A1 illustrated in FIG. 7 and pads that are connected to the sensing electrodes located in the first area A1.

Referring to FIG. 8, the sensing electrodes SE may be arranged to be spaced apart from each other in the first direction DR1 and the second direction DR2. That is, the sensing electrodes SE may be arranged in a matrix form. The first direction DR1 may correspond to a row and the second direction DR2 may correspond to a column. Accordingly, the sensing electrodes SE may be arranged in a plurality of rows and a plurality of columns.

The sensing lines SNL may be connected to the sensing electrodes SE in the active area AA, respectively, and extend in the second direction DR2. Sensing lines SNL that are connected to the sensing electrodes SE that are arranged in the k-th column (e.g., corresponding to the second direction DR2) may overlap the sensing electrodes SE that are arranged in the k-th column, respectively, and may extend in the second direction DR2. “k” is a natural number.

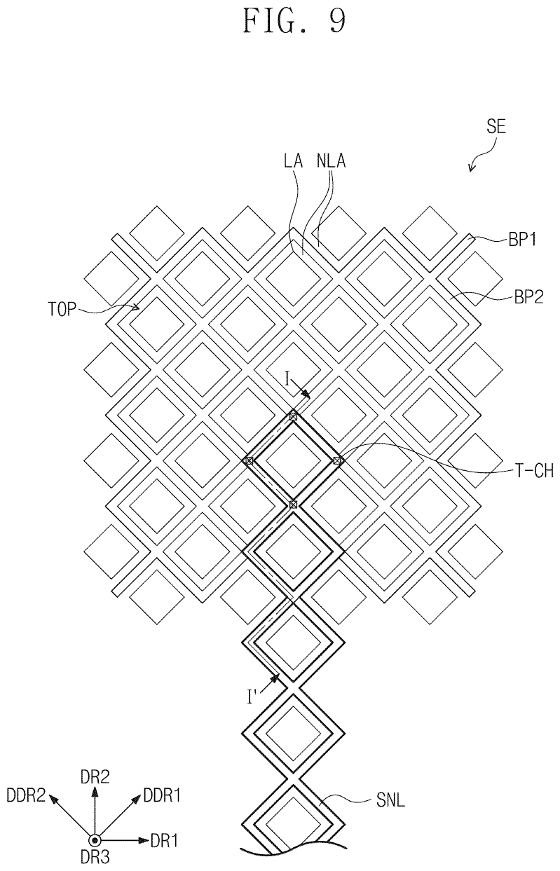

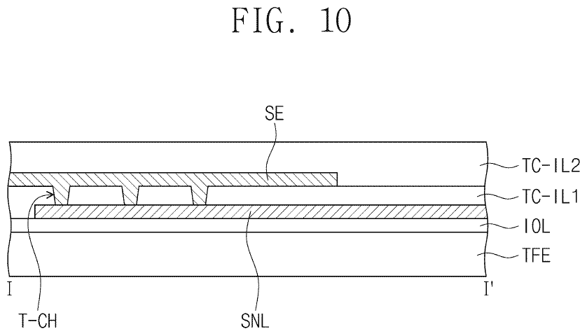

The sensing lines SNL may be located on a layer different from that of the sensing electrodes SE. For example, the sensing lines SNL may be located below the sensing electrodes SE. The sensing lines SNL may be connected to the sensing electrodes SE through a contact holes T-CH. Such a configuration will be described in more detail with reference to FIGS. 9 and 10.

The sensing lines SNL located in the active area AA may extend to the inactive area NAA and may be connected to the pads I-PD, respectively. The sensing lines SNL may be bent and extend in the inactive area NAA.

FIG. 9 is an enlarged view of a sensing electrode, for illustrating a detailed configuration of any one sensing electrode illustrated in FIG. 8. FIG. 10 is a cross-sectional view taken along the line I-I′ illustrated in FIG. 9.

By way of example, in FIG. 9, the sensing line SNL is illustrated as having a structure that is connected to a center of the sensing electrode SE.

Referring to FIG. 9, the sensing electrode SE and the sensing line SNL may have a mesh shape. For example, each of the sensing electrode SE and the sensing line SNL may include a plurality of first branch parts BP1 that extend in a first diagonal direction DDR1, and a plurality of second branch parts BP2 that extend in a second diagonal direction DDR2.

The first diagonal direction DDR1 may be defined as a direction that crosses the first and second directions DR1 and DR2 on a plane that is defined by the first and second directions DR1 and DR2. The second diagonal direction DDR2 may be defined as a direction that crosses the first diagonal direction DDR1 on a plane that is defined by the first and second directions DR1 and DR2. By way of example, the first direction DR1 and the second direction DR2 may perpendicularly cross each other, and the first diagonal direction DDR1 and the second diagonal direction DDR2 may perpendicularly cross each other.

The first branch parts BP1 and the second branch parts BP2 may cross each other, and may be formed integrally with each other. An opening TOP having a rhombus shape may be defined by the first branch parts BP1 and the second branch parts BP2 that cross each other. The first and second branch parts BP1 and BP2 may be defined by mesh lines, and a line width of each of the mesh lines may be several micrometers. The first and second branch parts BP1 and BP2 may include metal.

The light emission areas LA may have a rhombus shape and may be arranged to overlap the openings TOP. The first and second branch parts BP1 and BP2 may be arranged to overlap the non-light emission area NLA. The light emission area LA illustrated in FIG. 6 may be one of the light emission areas LA illustrated in FIG. 9.

Because the first and second branch parts BP1 and BP2 are located in the non-light emission area NLA, light generated in the light emission areas LA may be normally emitted while not being affected by the first and second branch parts BP1 and BP2.

Referring to FIGS. 9 and 10, an insulation layer IOL may be located on a thin film encapsulation layer TFE. The insulation layer IOL may include an inorganic insulation layer. A sensing line SNL may be located on the insulation layer IOL.

A first insulation layer TC-IL1 may be located on the insulation layer IOL to cover the sensing line SNL. The first insulation layer TC-IL1 may include an inorganic insulation layer or an organic insulation layer.

The sensing electrode SE may be located on the first insulation layer TC-IL1. The sensing electrode SE may be connected to the sensing line SNL through the plurality of contact holes T-CH defined in the first insulation layer TC-IL1.

A second insulation layer TC-IL2 may be located on the first insulation layer TC-IL1 to cover the sensing electrode SE. The second insulation layer TC-IL2 may include an organic insulation layer.

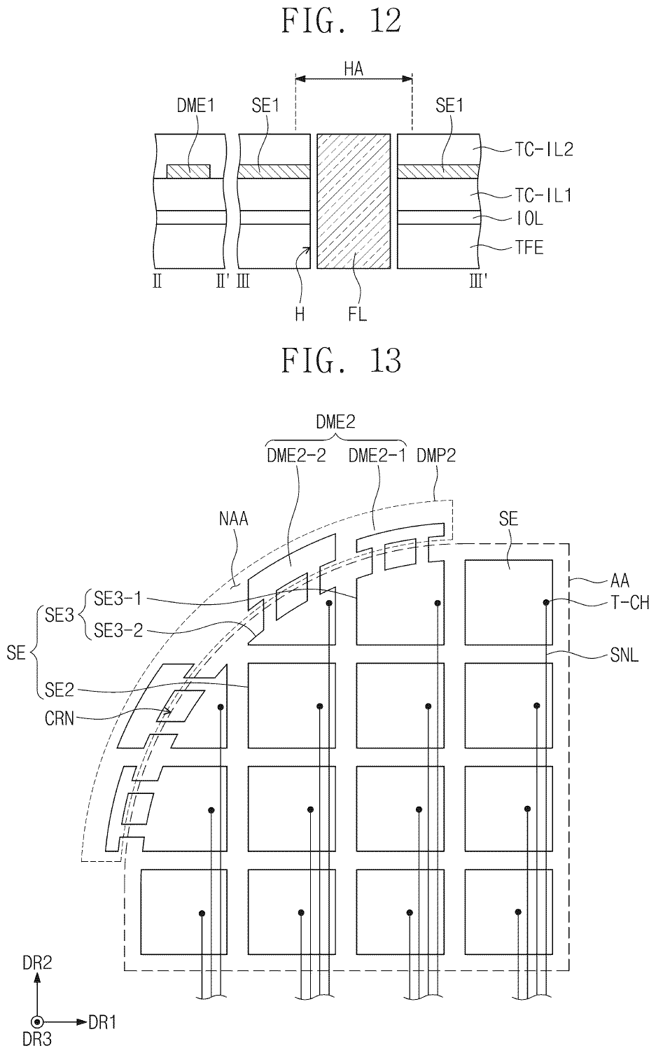

FIG. 11 is an enlarged view illustrating a portion of an input sensing part that is adjacent to a hole illustrated in FIG. 7. FIG. 12 is a cross-sectional view taken along the lines II-II′ and III-III′ illustrated in FIG. 11.

In FIG. 11, the first dummy part DMP1 illustrated in FIG. 7 is illustrated together with the sensing electrodes SE around the hole “H”, and in FIG. 12, cross-sections of the line II-II′ and the line III-III′ are illustrated together.

Referring to FIG. 11, the sensing electrodes SE may include a plurality of first sensing electrodes SE1 and a plurality of second sensing electrodes SE2. The first sensing electrodes SE1 may be located adjacent to the hole “H”. The first sensing electrodes SE1 may be arranged to surround the hole “H”. The second sensing electrodes SE2 may be arranged to be more spaced apart from the hole “H” than the first sensing electrodes SE1. The first sensing electrodes SE1 and the second sensing electrodes SE2 may be arranged in a matrix form.

The first sensing electrodes SE1 may be the irregular sensing electrodes described above. The second sensing electrodes SE2 may be the regular sensing electrodes described above. The sensing lines SNL may be connected to the first and second sensing electrodes SE1 and SE2 in the active area AA, respectively, to extend in the second direction DR2.

The first sensing electrodes SE1 may have a shape (e.g., in a plan view), of which some areas are removed from a rectangular shape. By way of example, in FIG. 11, the areas removed from the first sensing electrodes SE1 are illustrated by dotted lines. The second sensing electrodes SE2 may have the same shape and have a rectangular shape.

When viewed on a plane (or in a plan view), the first sensing electrodes SE1 may have a shape that is different from that of the second sensing electrodes SE2. When viewed on a plane (or in a plan view), the first sensing electrodes SE1 may have a size (or an extent) that is smaller than that of the second sensing electrodes SE2.

As the shapes of the first sensing electrodes SE1 are deformed from the rectangular shape, the edges of the first sensing electrodes SE1, which faces the hole “H”, may have a curved shape. The edges of the first sensing electrodes SE1, which do not face the hole “H”, may have sides that extend in the first direction DR1 and the second direction DR2.

The edges of the first sensing electrodes SE1, which faces the hole “H”, may have a curved shape corresponding to the edges of the hole “H”. When viewed on a plane (or in a plan view), the edges of the first sensing electrodes SE1, which face the hole “H”, may overlap the edges of the hole “H”.

Referring to FIGS. 11 and 12, a hole area HA may be defined in the active area AA. The hole “H” may be formed in the hole area HA. The first sensing electrodes SE1 may not be formed to the edge of the hole area HA, but may be formed to extend to the edge of the hole “H”. The extent of the first sensing electrodes SE1 may be expanded when the first sensing electrodes SE1 are formed to extend to the edge of the hole “H” rather than when the first sensing electrodes SE1 are formed to the edge of the hole area HA.

A functional element FL may be located in the hole “H”. By way of example, the functional element FL may be a watch, a camera, or a sensor.

The first dummy part DMP1 may include a plurality of first dummy electrodes DME1. The first dummy electrodes DME1 may be located in the inactive area NAA that is adjacent to the active area AA. The first dummy electrodes DME1 may be arranged in the first direction DR1.

The first dummy electrodes DME1 may be located on the first insulation layer TC-IL1. The second insulation layer TC-IL2 may be located on the first insulation layer TC-IL1 to cover the first dummy electrodes DME1. Accordingly, the first dummy electrodes DME1 and the first sensing electrodes SE1 may be located on the same layer.

According to some embodiments, the second sensing electrodes SE2 may also be located on the same layer as the first dummy electrodes DME1. Accordingly, the first and second sensing electrodes SE1 and SE2 and the first dummy electrodes DME1 may be located on the same layer. As described in FIG. 10, because the sensing lines SNL are located on an insulation layer IOL, the first and second sensing electrodes SE1 and SE2 and the first dummy electrodes DME1 may be located on the sensing lines SNL in the active area AA.

The first sensing electrodes SE1 may be connected to the first dummy electrodes DME1, respectively. The sensing lines SNL connected to the first sensing electrodes SE1 may extend toward the first dummy electrodes DME1, and may be connected to the first dummy electrodes DME1 in the inactive area NAA, respectively. Similar to the configuration illustrated in FIG. 10, the first dummy electrodes DME1 may be connected to the sensing lines SNL connected to the first sensing electrodes SE1 through contact holes T-CH defined in the first encapsulation layer TC-IL1.

Capacitances that are formed by the sensing electrodes SE may be uniformly formed when the sensing electrodes SE have the same size. However, the first sensing electrodes SE1 that is adjacent to the hole “H” may have a shape that is different from that of the second sensing electrodes SE2 and may have a size that is smaller than that of the second sensing electrodes SE2.

In this case, capacitances that are formed by the first and second sensing electrodes SE1 and SE2 may be different from the capacitances formed by the first sensing electrodes SE1, and the capacitances formed by the second sensing electrodes SE2. That is, a uniformity of capacitance may be lowered

According to some embodiments of the present disclosure, extents of the first sensing electrodes SE1 having a size that is smaller than that of the second sensing electrodes SE2 may be compensated for by the first dummy electrodes DME1. Because the first sensing electrodes SE1 are connected to the first dummy electrodes DME1, respectively, extents of the first sensing electrodes SE1 may be expanded.

Because the extents of the first sensing electrodes SE1 are expanded to correspond to the extents of the second sensing electrodes SE2, capacitances formed by the sensing electrodes SE may be similarly formed. As a result, the uniformity of capacitances may be relatively improved.

Sizes of the first dummy electrodes DME1 may be set differently depending on sizes of the first sensing electrodes SE1. For example, the first dummy electrode DME1 connected to the first sensing electrode SE1 having a smaller size may have a larger size. On the contrary, the first dummy electrode DME1 connected to the first sensing electrode SE1 having a larger size may have a smaller size.

For example, the first sensing electrodes SE1 may include a (1-1)-th sensing electrode SE1-1 and a (1-2)-th sensing electrode SE1-2, which have different sizes. The removed extent (indicated by a dotted line) of the (1-1)-th sensing electrode SE1-1 may be smaller than the removed extent (indicated by a dotted line) of the (1-2)-th sensing electrode SE1-2. Accordingly, the (1-2)-th sensing electrode SE1-2 may have a size smaller than that of the (1-1)-th sensing electrode SE1-1.

The first dummy electrode DME1 may include a (1-1)-th dummy electrode DME1-1 that is connected to the (1-1)-th sensing electrode SE1-1 and a (1-2)-th dummy electrode DME1-2 that is connected to the (1-2)-th sensing electrode SE1-2. Because the (1-1)-th sensing electrode SE1-1 is larger and the (1-2)-th sensing electrode SE1-2 is smaller, the (1-2)-th dummy electrode DME1-2 may have a size that is larger than that of the (1-1)-th dummy electrode DME1-1.

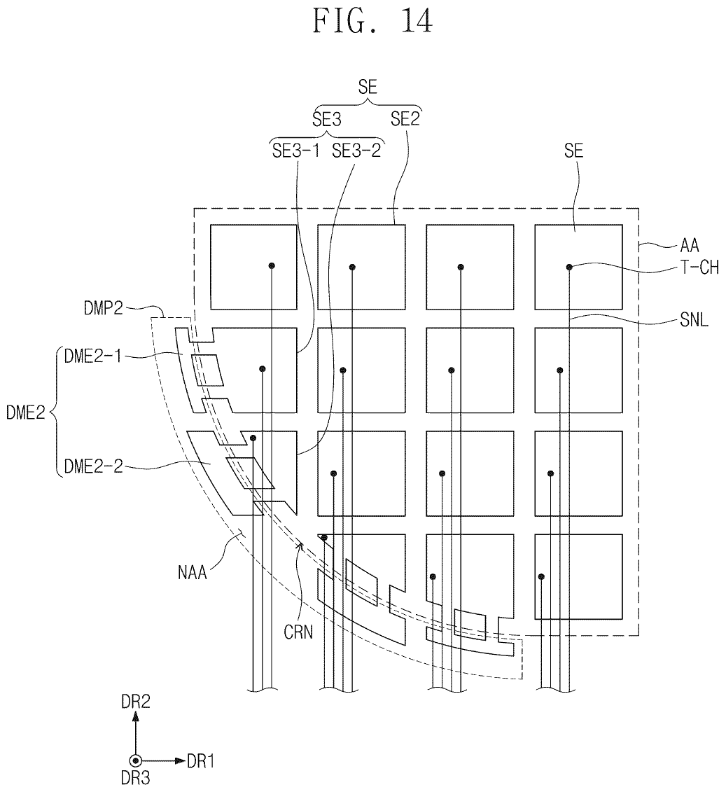

FIG. 13 is an enlarged view of a portion of an input sensing part that is adjacent to a corner part located at a left upper end of an active area illustrated in FIG. 7. FIG. 14 is an enlarged view of a portion of an input sensing part that is adjacent to a corner part located at a lower left end of an active area illustrated in FIG. 7.

Referring to FIGS. 13 and 14, the sensing electrodes SE and the second dummy part DMP2 that are adjacent to the corner part CRN illustrated in FIG. 13 and the sensing electrodes SE and the second dummy part DMP2 that are adjacent to the corner part CRN illustrated in FIG. 14 are only symmetrical in the second direction DR2, and may have the same (or substantially the same) shape. Accordingly, the configuration illustrated in FIG. 13 will be mainly described below.

According to some embodiments, the sensing electrodes SE and the second dummy part DMP2 that are adjacent to the corner parts CRN located at an upper right end and a lower right end of the active area AA illustrated in FIG. 7 may have shapes that are symmetrical to the corner parts CRN illustrated in FIGS. 13 and 14 in the first direction.

The sensing electrodes SE may include a plurality of second sensing electrodes SE2 and a plurality of third sensing electrodes SE3. The third sensing electrodes SE3 may be located adjacent to the corner part CRN. The second sensing electrodes SE2 may be located to be more spaced apart from the corner part CRN than the third sensing electrodes SE3 in the first and second directions DR1 and DR2.

The second sensing electrodes SE2 may have a rectangular shape as the second sensing electrodes SE2 illustrated in FIG. 11. The third sensing electrodes SE3 may be the above-described irregular sensing electrode.

The second and third sensing electrodes SE2 and SE3 may be arranged in a matrix form. The sensing lines SNL may be connected to the second and third sensing electrodes SE2 and SE3 in the active area AA, respectively, to extend in the second direction DR2.

When viewed on a plane (or in a plan view), the third sensing electrodes SE3 may have a shape that is different from that of the second sensing electrodes SE2. When viewed on a plane (or in a plan view), the third sensing electrodes SE3 may have a size (or an extent) that is smaller than that of the second sensing electrodes SE2.

Edges of the third sensing electrodes SE3, which face the corner part CRN, may have a curved shape corresponding to the corner part CRN. Edges of the third sensing electrodes SE3, which do not face the corner part CRN, may have sides that extend in the first and second directions DR1 and DR2.

The second dummy part DMP2 may include a plurality of second dummy electrodes DME2. The second dummy electrodes DME2 may be located in an inactive area NAA that is adjacent to the corner part CRN. The second dummy electrodes DME2 may be arranged along the corner part CRN.

According to some embodiments, the second dummy electrodes DME2 may be located on the same layer as the first dummy electrodes DME1 illustrated in a cross section in FIG. 12. Furthermore, the third sensing electrodes SE3 may be located on the same layer as the second sensing electrodes SE2. Accordingly, the second dummy electrodes DME2 and the third sensing electrodes SE3 may be located on the same layer as the third sensing electrodes SE3. The second dummy electrodes DME2 and the third sensing electrodes SE3 may be located on an upper side of the sensing lines SNL.

The third sensing electrodes SE3 may be connected to the second dummy electrodes DME2, respectively. Each of the second dummy electrodes DME2 may extend from the corresponding third sensing electrode SE3, among the third sensing electrodes SE3, and may be formed integrally with the corresponding third sensing electrode SE3.

The third sensing electrodes SE3 that is adjacent to the corner part CRN may have a shape that is different from that of the second sensing electrodes SE2 and may have a size that is smaller than that of the second sensing electrodes SE2. In this case, capacitances that are formed by the second and third sensing electrodes SE2 and SE3 may be different from the capacitances formed by the third sensing electrodes SE3, and the capacitances formed by the second sensing electrodes SE2. That is, a uniformity of capacitance may be lowered

According to some embodiments of the present disclosure, extents of the third sensing electrodes SE3 having a size that is smaller than that of the second sensing electrodes SE2 may be compensated for by the second dummy electrodes DME2. Because the third sensing electrodes SE3 are connected to the second dummy electrodes DME2, respectively, extents of the third sensing electrodes SE3 may be expanded.

Because the extents of the third sensing electrodes SE3 are expanded to correspond to the extents of the second sensing electrodes SE2, capacitances formed by the sensing electrodes SE may be similarly formed. As a result, the uniformity of capacitances may be relatively improved.

Sizes of the second dummy electrodes DME2 may be set differently depending on sizes of the third sensing electrodes SE3. The second dummy electrode DME2 connected to the third sensing electrode SE3 having a smaller size may have a larger size, and the second dummy electrode DME2 connected to the third sensing electrode SE3 having a larger size may have a smaller size.

The third sensing electrodes SE3 may include a (3-1)-th sensing electrode SE3-1 and a (3-2)-th sensing electrode SE3-2 that have different sizes. The (3-2)-th sensing electrode SE3-2 may have a size that is smaller than that of the (3-1)-th sensing electrode SE3-1.

The second dummy electrode DME2 may include a (2-1)-th dummy electrode DME2-1 that is connected to the (3-1)-th sensing electrode SE3-1, and a (2-2)-th dummy electrode DME2-2 that is connected to the (3-2)-th sensing electrode SE3-2. Because the (3-1)-th sensing electrode SE3-1 is larger and the (3-2)-th sensing electrode SE3-2 is smaller, the (2-2)-th dummy electrode DME2-2 may have a size larger than that of the (2-1)-th dummy electrode DME2-1.

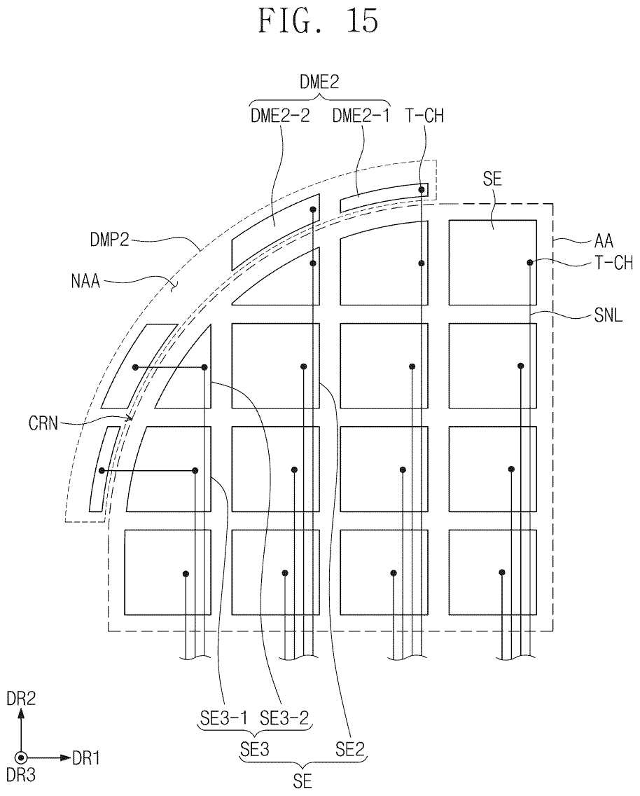

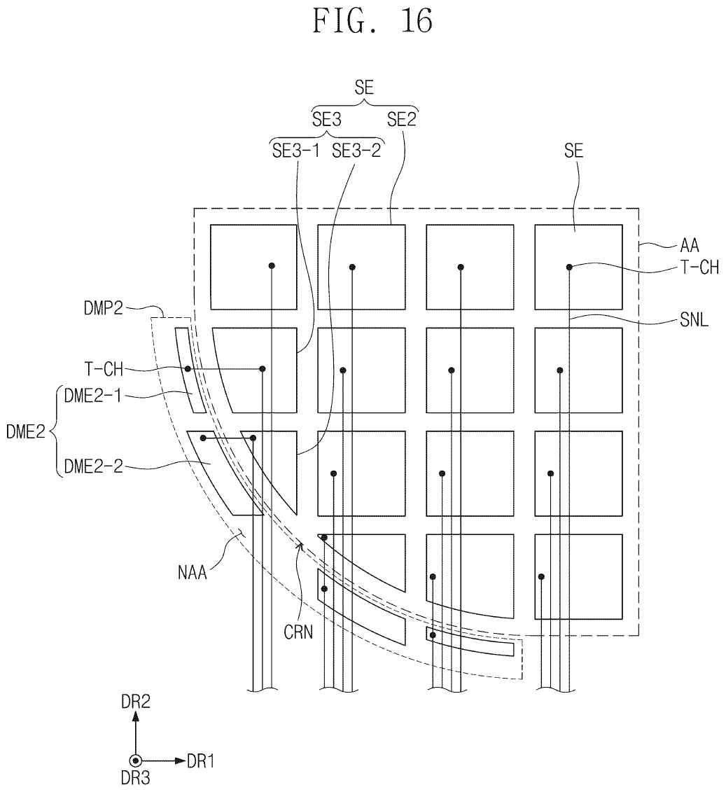

FIGS. 15 and 16 are views illustrating a connection configuration of third sensing electrodes that are adjacent to corner parts, and second dummy electrodes according to some embodiments of the present disclosure.

By way of example, FIG. 15 is illustrated as a plane corresponding to FIG. 13, and FIG. 16 is illustrated as a plane corresponding to FIG. 14. Hereinafter, the configurations illustrated in FIGS. 15 and 16 will be described mainly with reference to configurations that are different from those illustrated in FIGS. 13 and 14.

Referring to FIGS. 15 and 16, the third sensing electrodes SE3 may be connected to the second dummy electrodes DME2 through sensing lines SNL. For example, the sensing lines SNL connected to the third sensing electrodes SE3 may extend to the inactive area NAA that is adjacent to the corner part CRN, and may be connected to the second dummy electrodes DME2, respectively.

Similar to the configuration illustrated in FIG. 10, the second dummy electrodes DME2 may be connected to the sensing lines SNL through contact holes T-CH, respectively.

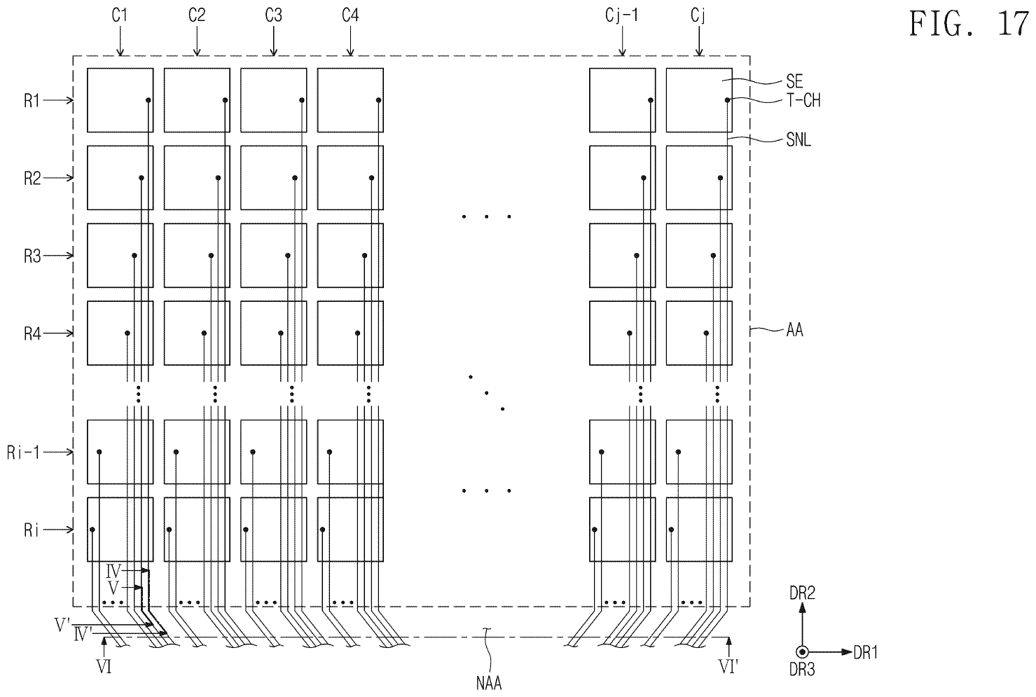

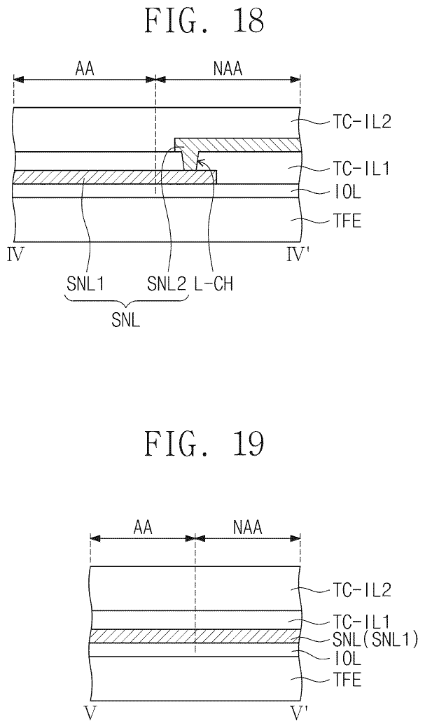

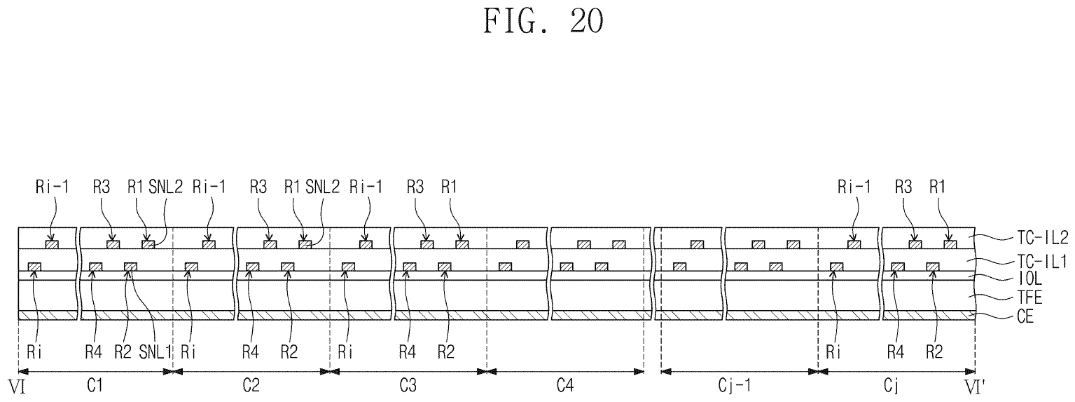

FIG. 17 is a more planar view illustrating sensing electrodes and sensing lines illustrated in FIG. 7. FIG. 18 is a cross-sectional view taken along the line IV-IV′ illustrated in FIG. 17. FIG. 19 is a cross-sectional view taken along the line V-V′ illustrated in FIG. 17. FIG. 20 is a cross-sectional view taken along the line VI and VI′ illustrated in FIG. 17.

In FIG. 17, to further highlight an arrangement state of the sensing electrodes SE and the sensing lines SNL on a plane, the corner parts CRN and the hole “H” are omitted, and by way of example, the sensing electrodes SE are illustrated as having the same rectangular shape. In FIG. 17, line IV-IV′, line V-V′, and line VI-VI′ are illustrated as overlapping the sensing lines SNL.

Referring to FIG. 17, the sensing electrodes SE may be arranged in a plurality of rows R1 to Ri and a plurality of columns C1 to Cj. “i” and “j” are natural numbers of 2 or more. The sensing lines SNL may be connected to the sensing electrodes SE, respectively, to extend to an inactive area NAA that is adjacent to a lower side of the active area AA. The sensing lines SNL may be bent and extend in the inactive area NAA.

Referring to FIGS. 17 and 18, the sensing lines SNL connected to the sensing electrodes SE located in the first row R1 may be located on different layers in the active area AA and the inactive area NAA. For example, the sensing line SNL connected to the sensing electrode SE located in the first row R1 and the first column C1 may include a first sensing line SNL1 and a second sensing line SNL2 that are located on the first sensing line SNL1.

The first sensing line SNL1 may be located on the insulation layer IOL in the active area AA. The first sensing line SNL1 may extend to the inactive area NAA that is adjacent to a boundary between the active area AA and the inactive area NAA.

The second sensing line SNL2 may be located on the first insulation layer TC-IL1 in the inactive area NAA. The second sensing line SNL2 may be connected to the first sensing line SNL1 in the inactive area NAA that is adjacent to the active area AA through a contact hole L-CH defined in the first insulation layer TC-IL1.

The sensing line SNL connected to the sensing electrode SE located in the first row R1 and the first column C1 may be located on the insulation layer IOL in the active area AA, and may be located on the first insulation layer TC-IL1 in the inactive area NAA. That is, the layer, on which the sensing line SNL connected to the sensing electrode SE located in the first row R1 and the first column C1 is located, may be changed in the inactive area NAA.

Sensing lines SNL connected to the sensing electrodes SE located in the odd-numbered rows R1, R3, . . . , and Ri-1 may have a configuration illustrated in FIG. 18. Accordingly, the sensing lines SNL connected to the sensing electrodes SE located in the odd-numbered rows R1, R3, . . . , and Ri-1 may be located on the first insulation layer TC-IL1 in the inactive area NAA. The lamination structure will be illustrated in FIG. 20 below.

Referring to FIGS. 17 and 19, the sensing lines SNL connected to the sensing electrodes SE located in the second row R2 may be located on the same layer in the active area AA and the inactive area NAA. For example, the sensing line SNL connected to the sensing electrode SE located in the second row R2 and the first column C1 may include a first sensing line SNL1 located on the insulation layer IOL in the active area AA and the inactive area NAA.

Sensing lines SNL connected to the sensing electrodes SE located in the even-numbered rows R2, R2, . . . , and Ri may have a configuration illustrated in FIG. 19. Accordingly, the sensing lines SNL connected to the sensing electrodes SE located in the even-numbered rows R2, R4, . . . , and Ri may be located on the insulation layer IOL in the inactive area NAA. The lamination structure will be illustrated in FIG. 20 below.

Hereinafter, in FIG. 20, signs of rows R1 to Ri and columns C1 to Cj are illustrated with respect to cross sections of the sensing lines SNL. The signs of rows R1 to Ri and columns C1 to Cj may indicate sensing lines SNL that are connected to the sensing electrodes SE arranged in rows R1 to Ri and columns C1 to Cj.

Referring to FIGS. 17 and 20, in the inactive area NAA, the second sensing lines SNL2 that are connected to the sensing electrodes SE arranged on the odd-numbered rows R1, R3, . . . , and Ri-1 may be located on the first insulation layer TC-IL1 and may be located on the same layer. In the inactive area NAA, the first sensing lines SNL1 that are connected to the sensing electrodes SE located on the even-numbered rows R2, R4, . . . , and Ri may be located on the insulation layer IOL and may be located on the same layer.

In the inactive area NAA, the second sensing lines SNL2 connected to the sensing electrodes SE arranged in the odd-numbered rows R1, R3, . . . , and Ri-1 and the first sensing lines SNL1 connected to the sensing electrodes SE arranged in the even-numbered rows R2, R4, . . . , and Ri may be located on different layers, and may be alternately arranged with each other.

In the inactive area NAA, because the sensing lines SNL that are connected to the sensing electrodes SE located in the same row are located on the same layer, the sensing lines SNL may be spaced apart from the second electrode CE at the same interval in the third direction DR3.

For example, because the second sensing lines SNL2 that are connected to the sensing electrodes SE located in the (i-1)-th rows Ri-1 are located on the same layer, they may be spaced apart from the second electrode CE at the same interval in the third direction DR3. Accordingly, the second sensing lines SNL2 may form the same capacitance for the second electrode CE.

Furthermore, because the first sensing lines SNL1 that are connected to the sensing electrodes SE arranged in the i-th row Ri are located on the same layer, they may be spaced apart from the second electrode CE at the same interval in the third direction DR3. Accordingly, the first sensing lines SNL1 may form the same capacitance for the second electrode CE.

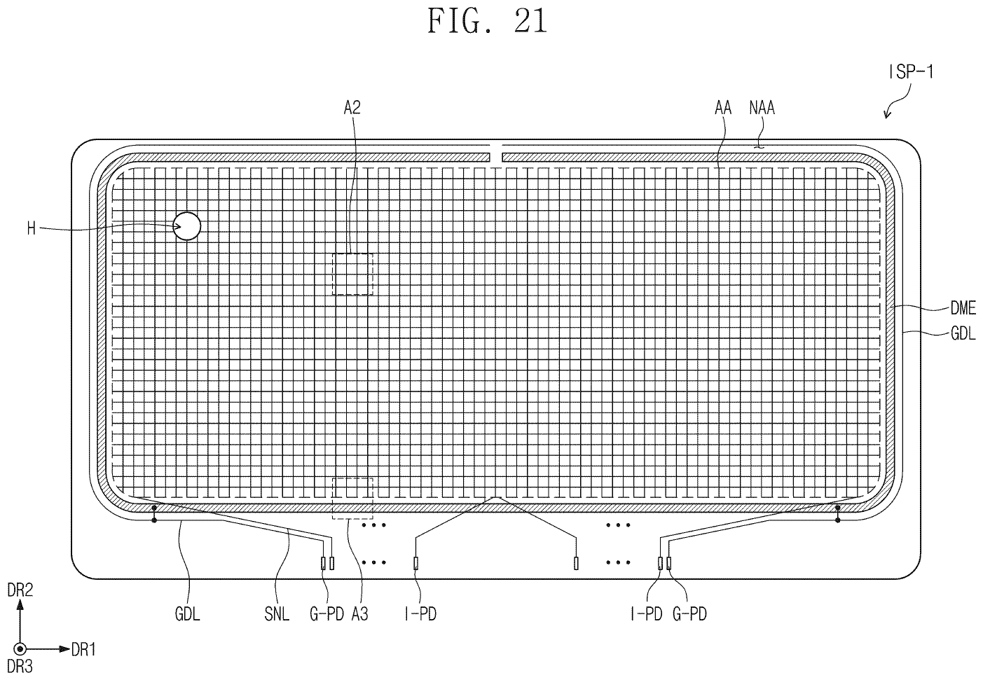

FIG. 21 is a plan view of an input sensing part according to some embodiments of the present disclosure.

FIG. 21 is a plan view corresponding to FIG. 7, and hereinafter, a configuration of an input sensing part ISP-1 illustrated in FIG. 21 will be described, focusing on a configuration that is different from a configuration illustrated in FIG. 7.

Referring to FIG. 21, the input sensing part ISP-1 may include a dummy electrode DME. The dummy electrode DME may be located in the inactive area NAA to surround the active area AA. A portion of the dummy electrode DME may be opened. For example, a portion of the dummy electrode DME, which is adjacent to an upper side of the active area AA, may be opened. Accordingly, the dummy electrode DME may have a loop shape, of which a portion is opened. The dummy electrode DME may be located adjacent to the sensing electrodes SE that are adjacent to a edge of the active area AA.

The input sensing part ISP-1 may further include pads G-PD and guard lines GDL. The pads G-PD may be located in an inactive area NAA that is adjacent to a lower side of the input sensing part ISP-1. The pads G-PD may be located on an outside of the pads I-PD. The pads I-PD may be located between the pads G-PD.

The guard lines GDL may be located in the inactive area NAA and may be connected to the pads G-PD, respectively. The guard lines GDL may be located on an outer side of the dummy electrode DME, and may extend along the dummy electrode DME. The guard lines GDL may be spaced apart from each other in the inactive area NAA that is adjacent to an upper side of the active area AA.

The guard lines GDL may be connected to the dummy electrode DME. The guard lines GDL may receive a DC voltage through the pads G-PD. The dummy electrode DME may receive a DC voltage through the guard lines GDL.

According to some embodiments, a ground line may be located on an outer side of the guard line, and a ground voltage may be applied to the ground line. In this case, a coupling phenomenon may occur between the ground line and the sensing lines SNL due to a potential difference between the ground line and the sensing lines SNL. That is, noise may occur due to signal interference therebetween.

To reduce this phenomenon, a DC voltage having a specific level may be applied to the guard line GDL. The guard line GDL may reduce a coupling phenomenon between the ground line and the sensing lines SNL, between the ground line and the sensing lines SNL.

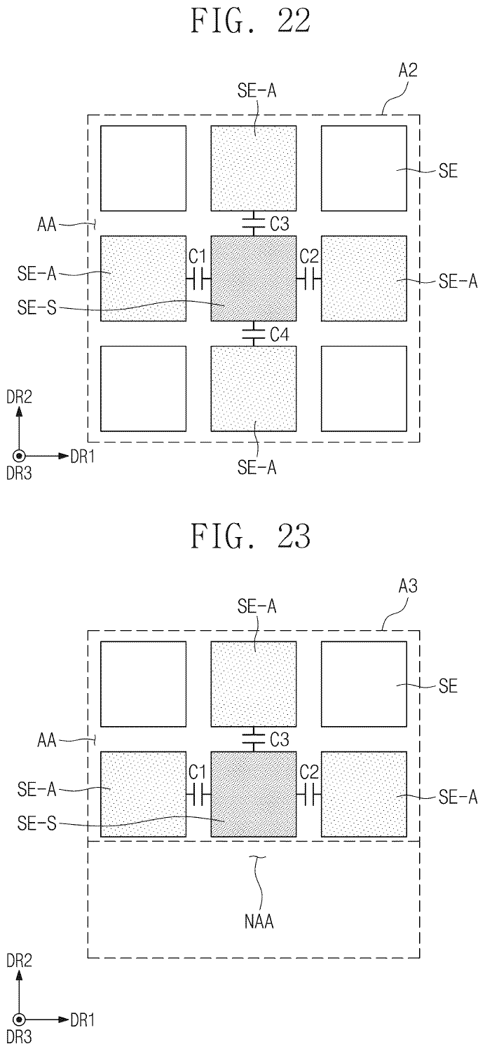

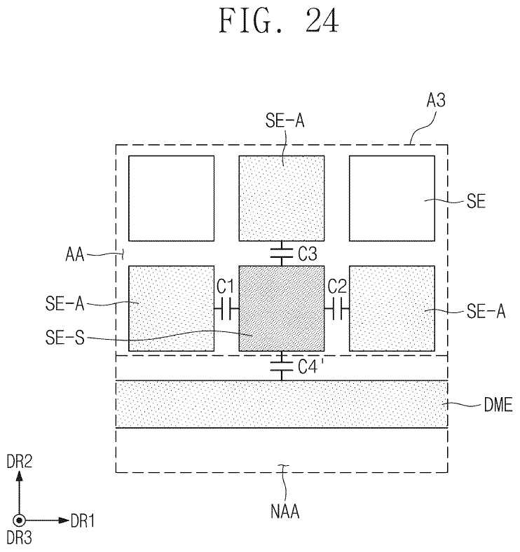

FIG. 22 is an enlarged view of sensing electrodes that are located in a second area A2 illustrated in FIG. 21. FIG. 23 is an enlarged view illustrating sensing electrodes in a state, in which dummy electrodes are removed from a third area A3 illustrated in FIG. 21. FIG. 24 is an enlarged view of sensing electrodes a dummy electrode that are located in a third area A3 illustrated in FIG. 21.

Referring to FIG. 22, the first, second, third, and fourth capacitances C1, C2, C3, and C4 may be formed by the sensing electrode SE-S touched by the user, among the sensing electrodes SE, and the sensing electrodes SE-A around the sensing electrode SE-S.

Referring to FIG. 23, the first, second, and third capacitances C1, C2, and C3 may be formed by the sensing electrode SE-S touched by the user, among the sensing electrodes SE, and the sensing electrodes SE-A around the sensing electrode SE-S.

Referring to FIGS. 22 and 23, capacitances formed by the sensing electrodes SE that are adjacent to the edge of the active area AA and capacitances formed by the sensing electrodes SE of a central area of the active area AA, which is spaced apart from the edge of the active area AA, may be different from each other. That is, a uniformity of the capacitances may be lowered, and in this case, sensing data may be different.

Referring to FIG. 24, the first, second, and third capacitances C1, C2, and C3 may be formed by the sensing electrode SE-S and the sensing electrodes SE-A around the sensing electrode SE-S, and additionally, a fourth capacitance C4′ may be formed by the sensing electrode SE-S and the dummy electrode DME. Accordingly, the capacitances formed by the sensing electrodes SE that is adjacent to the edge of the active area AA and the capacitances formed by the sensing electrodes SE of the central area of the active area AA may be similarly formed to relatively improve a uniformity of the capacitance.

According to some embodiments of the present disclosure, because the sensing electrodes that are adjacent to the corner parts of the hole and the active area are connected to the dummy electrodes located in the inactive area, the extents of the sensing electrodes that are adjacent to the corner parts of the hole and the active area may be compensated for. Accordingly, a uniformity of the capacitances formed by the sensing electrodes may be relatively improved.

In addition, the dummy electrodes may be located in the inactive area to surround the active area. Accordingly, the capacitances formed by the sensing electrodes that are adjacent to the edge of the active area and the capacitances formed by the sensing electrodes in the center area of the active area may be formed similarly, so that the uniformity of the capacitances may be relatively improved.

Although aspects of some embodiments of the present disclosure has been described with reference to the embodiments, it will be appreciated by an ordinary skilled in the art, to which the present disclosure pertains, that the present disclosure may be modified and changed within the scope of the appended claims, and their equivalents without departing from the spirits and technical field of the present disclosure. Therefore, the technical scope of embodiments according to the present disclosure should not be limited to the detailed description of the specification, but should be determined by the appended claims, and their equivalents.

What is claimed is:

1. An input sensing part comprising:
a plurality of sensing electrodes in an active area;
a plurality of sensing lines connected to the sensing electrodes, respectively; and
a plurality of first dummy electrodes in an inactive area around the active area,
wherein a hole is defined in the active area, and
wherein the sensing electrodes include:
a plurality of first sensing electrodes adjacent to the hole, and connected to the first dummy electrodes, respectively; and
a plurality of second sensing electrodes spaced apart from the hole further than the first sensing electrodes.

2. The input sensing part of claim 1, wherein in a plan view, the first sensing electrodes have a shape different from that of the second sensing electrodes.

3. The input sensing part of claim 1, wherein in a plan view, the first sensing electrodes have a size smaller than that of the second sensing electrodes.

4. The input sensing part of claim 1, wherein sensing lines connected to the first sensing electrodes extend to the inactive area to be connected to the first dummy electrodes.

5. The input sensing part of claim 1, wherein the first sensing electrodes include:
a (1-1)-th sensing electrode; and
a (1-2)-th sensing electrode having a size smaller than that of the (1-1)-th sensing electrode.

6. The input sensing part of claim 5, wherein the first dummy electrodes include:
a (1-1)-th dummy electrode connected to the (1-1)-th sensing electrode; and
a (1-2)-th dummy electrode connected to the (1-2)-th sensing electrode, and
wherein the (1-2)-th dummy electrode has a size greater than that of the (1-1)-th dummy electrode.

7. The input sensing part of claim 1, wherein edges of the first sensing electrodes, which face the hole, have curved shapes corresponding to a edge of the hole, and in a plan view, overlaps the edge of the hole.

8. The input sensing part of claim 1, wherein the first sensing electrodes, the second sensing electrodes, and the first dummy electrodes are above the sensing lines, and
wherein the first sensing electrodes, the second sensing electrodes, and the first dummy electrodes are on a same layer.

9. The input sensing part of claim 1, wherein the active area includes at least one corner part having a curved shape,
wherein the sensing electrodes further include a plurality of third sensing electrodes adjacent to the corner part, and
wherein edges of the third sensing electrodes, which face the corner part, have curved shapes corresponding to the corner part.

10. The input sensing part of claim 9, wherein the third sensing electrodes have a shape different from that of the second sensing electrodes, and
wherein in a plan view, the third sensing electrodes have a size smaller than that of the second sensing electrodes.

11. The input sensing part of claim 9, further comprising:
a plurality of second dummy electrodes in an inactive area adjacent to the corner part,
wherein the second dummy electrodes are connected to the third sensing electrodes, respectively.

12. The input sensing part of claim 11, wherein each of the second dummy electrodes extends from a corresponding one of the third sensing electrodes, and is formed integrally with the corresponding third sensing electrode.

13. The input sensing part of claim 11, wherein the third sensing electrodes and the second dummy electrodes are on a same layer.

14. The input sensing part of claim 11, wherein the third sensing electrodes include:
a (3-1)-th sensing electrode; and
a (3-2)-th sensing electrode having a size smaller than that of the (3-1)-th sensing electrode.

15. The input sensing part of claim 14, wherein the second dummy electrodes include:
a (2-1)-th dummy electrode connected to the (3-1)-th sensing electrode; and
a (2-2)-th dummy electrode connected to the (3-2)-th sensing electrode, and
wherein the (2-2)-th dummy electrode has a size greater than that of the (2-1)-th dummy electrode.

16. The input sensing part of claim 11, wherein the sensing lines connected to the third sensing electrodes extend to an inactive area adjacent to the corner part, and are connected to the second dummy electrodes, respectively.

17. The input sensing part of claim 1, wherein the sensing electrodes are arranged in a first direction, and a second direction crossing the first direction, and the first direction corresponds to rows and the second direction corresponds to columns,
wherein the sensing lines connected to the sensing electrodes arranged in an (i-1)-th row are on a same layer in the inactive area,
wherein the sensing lines connected to the sensing electrodes arranged in an i-th row are on a same layer in the inactive area, and
wherein the sensing lines connected to the sensing electrodes arranged in the (i-1)-th row and the sensing lines connected to the sensing electrodes arranged in the i-th row are on different layers in the inactive area, in which “i” is a natural number of two or more.

18. An input sensing part comprising:
a plurality of sensing electrodes in an active area;
a plurality sensing lines connected to the sensing electrodes, respectively;
a dummy electrode in an inactive area around the active area; and
a guard line in the inactive area, and to which a direct current is applied, and
wherein the dummy electrode surrounds the active area, a portion of the dummy electrode is opened, and the guard line is connected to the dummy electrode.

19. The input sensing part of claim 18, wherein the dummy electrode is adjacent to the sensing electrodes adjacent to a edge of the active area, and the guard line is on an outer side of the dummy electrode.

20. A display device comprising:
a display panel; and
an input sensing part on the display panel,
wherein the input sensing part includes:
a plurality of sensing electrodes in an active area; and
a plurality of first dummy electrodes in an inactive area around the active area,
wherein a hole is defined in the active area, and
wherein the sensing electrodes include:
a plurality of first sensing electrodes adjacent to the hole, and connected to the first dummy electrodes, respectively; and
a plurality of second sensing electrodes spaced apart from the hole further than the first sensing electrodes, and
wherein a size of the first dummy electrodes is set differently depending on a size of the first sensing electrodes.

21. An electronic device for provide an image comprising:
a display device comprising:
a display panel; and
an input sensing part on the display panel,
wherein the input sensing part includes:
a plurality of sensing electrodes in an active area; and
a plurality of first dummy electrodes in an inactive area around the active area,
wherein a hole is defined in the active area, and
wherein the sensing electrodes include:
a plurality of first sensing electrodes adjacent to the hole, and connected to the first dummy electrodes, respectively; and
a plurality of second sensing electrodes spaced apart from the hole further than the first sensing electrodes, and
wherein a size of the first dummy electrodes is set differently depending on a size of the first sensing electrodes.
